(19) United States
(12) Patent Application Publication
(10) Pub. No.: US 2026/0173922 A1
(43) Pub. Date: Jun. 18, 2026

(54) MESHED INTERCONNECTS AND POWER PLANES FOR GLASS CORE SUBSTRATES

(71) Applicant: Intel Corporation, Santa Clara, CA (US)

(72) Inventor: Telesphor KAMGAING, Chandler, AZ (US)

(21) Appl. No.: 18/984,450

(22) Filed: Dec. 17, 2024

(51) Int. Cl. H01L 23/498; H01L 23/15; H01L 23/34

(52) U.S. Cl. CPC H10W 70/65; H10W 40/00; H10W 70/635; H10W 70/692

(57) ABSTRACT

Embodiments disclosed herein include an apparatus that comprises a substrate, where the substrate comprises a glass layer. In an embodiment, the apparatus further comprises an electrically conductive feature on the substrate, where the electrically conductive feature directly contacts the glass layer. In an embodiment, the electrically conductive feature comprises a layer, and a plurality of holes through the layer. In an embodiment, a combined area of the plurality of holes is 20 percent or more of an area defined by an outer perimeter of the layer.

### BACKGROUND

Glass cores for package substrates are an attractive option due to the increased stiffness and planarity that they provide compared to existing organic cores. However, the brittle nature of glass provides several challenges with respect to manufacturing. For example, differences in expansion between the glass core and adjacent materials can lead to high stresses that can cause cracking or other damage to the glass core. This is particularly problematic in the case of copper structures that are in direct contact with the glass core due to the significant difference between the coefficients of thermal expansion (CTEs) of the glass material and the copper. Accordingly, copper features (e.g., traces, pads, planes, etc.) are spaced away from the glass core substrate by a dielectric buffer layer. The inclusion of an additional dielectric buffer layer increases the complexity of the package substrate, increases the thickness of the package substrate, and increases the cost of the package substrate.

### BRIEF DESCRIPTION OF THE DRAWINGS

FIG. 1A is a cross-sectional illustration of a package substrate with a glass core and buffer layers over the glass core to prevent cracking due to thermal expansion mismatches, in accordance with an embodiment.

FIGS. 1B and 1C are illustrations of a co-planar waveguide on a glass core with a buffer layer between the traces and the glass core, in accordance with an embodiment.

FIGS. 2A and 2B are illustrations of an electrically conductive trace with a meshed pattern that is in direct contact with an underlying glass core, in accordance with an embodiment.

FIGS. 2C and 2D are illustrations of an electrically conductive plane with a meshed pattern that is in direct contact with an underlying glass core, in accordance with an embodiment.

FIGS. 3A and 3B are illustrations of a co-planar waveguide that is in direct contact with an underlying glass core, in accordance with an embodiment.

FIG. 4 is a cross-sectional illustration of a package substrate with a glass core with electrically conductive features with meshed patterns in direct contact with the glass core, in accordance with an embodiment.

FIGS. 5A-5D are cross-sectional illustrations of package substrates with meshed electrically conductive features in direct contact with a glass core in order to form various types of interconnects, in accordance with different embodiments.

FIG. 6 is a cross-sectional illustration of an electronic system with a package substrate that comprises a glass core with meshed electrically conductive features in direct contact with the glass core, in accordance with an embodiment.

FIG. 7 is a schematic of a computing device built in accordance with an embodiment.

### EMBODIMENTS OF THE PRESENT DISCLOSURE

Described herein are glass substrates that are in direct contact with electrically conductive structures that have a meshed structure, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, existing glass cores provide stiffness and/or improved planarity compared to organic cores. However, it is not currently feasible to provide electrically conductive features (e.g., planes, pads, traces, etc.) directly on the glass core. This is due to the differences in the coefficient of thermal expansion (CTE) between the glass core and the metallic material of the electrically conductive features. When heated, the electrically conductive features expand faster than the glass core, and this expansion induces stress into the underlying glass core. The stress can reach a level that ultimately leads to cracking and/or other defects in the glass core. Accordingly, existing glass core solutions include a dielectric buffer layer between the glass core and any metallic features.

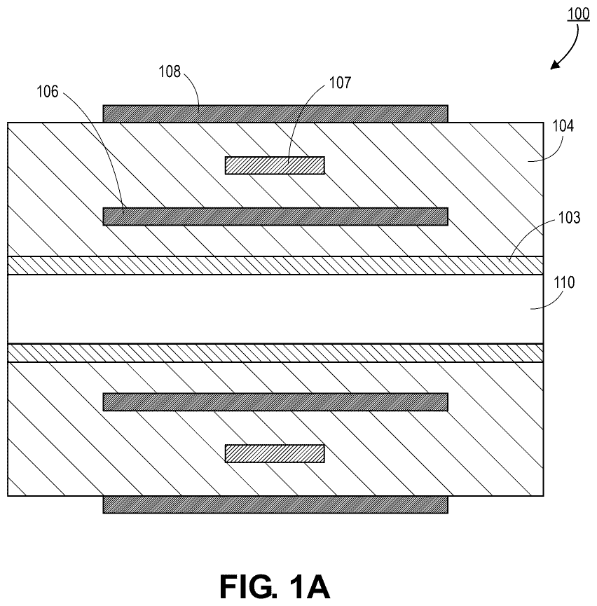

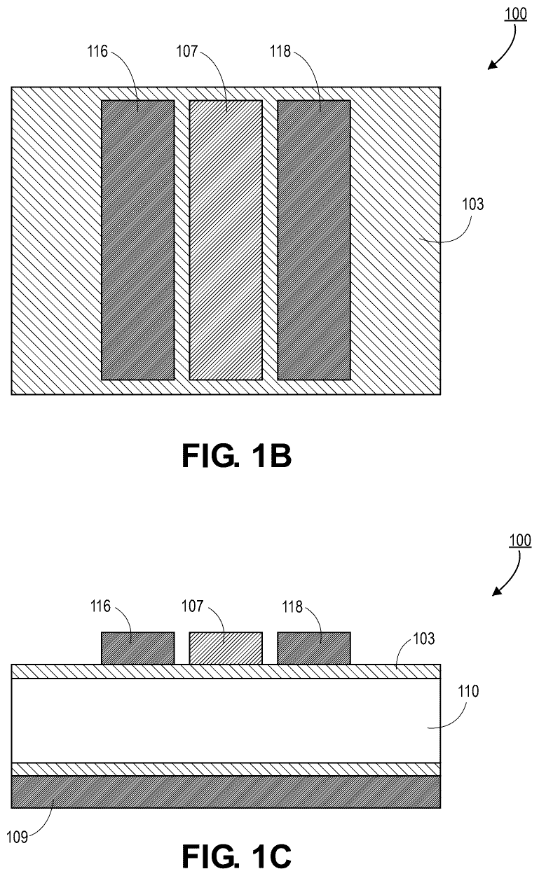

An example of such a structure is shown in FIG. 1A. FIG. 1A is a cross-sectional illustration of a package substrate 100 with a glass core 110. In order to protect the glass core 110, buffer layers 103 are provided over the top and/or bottom surface of the glass core 110. The buffer layers 103 may comprise dielectric material. Buildup layers 104 are provided on the buffer layers 103. In some instances, the buildup layers 104 and the buffer layers 103 may comprise the same material. For example, both the buffer layers 103 and the buildup layers 104 may comprise dielectric buildup film material in some instances.

In an embodiment, electrically conductive features, such as embedded planes 106 and traces 107 may be provided in the buildup layers 104. A plane 108 and/or trace may also be provided over the buildup layers 104 to provide a desired type of interconnect architecture. As shown, all of the electrically conductive features (e.g., plane 106, trace 107, and plane 108) are spaced away from the glass core 110 by the buffer layer 103. The buffer layer 103 provides a region that can absorb stress generated by the CTE mismatch between the metallic material of the electrically conductive features and the glass core 110.

Similarly, FIGS. 1B and 1C illustrate a co-planar waveguide configuration of a package substrate 100 with a glass core 110. As shown, the buffer layers 103 are provided on the top and bottom surfaces of the glass core 110. The signal trace 107, a first ground trace 116, and a second ground trace 118 are provide on the buffer layer 103. That is, the buffer layer 103 provides a stress mitigation layer between the electrically conductive features and the glass core 110. Similarly, a buffer layer 103 is provided between the glass core 110 and a ground plane 109 below the glass core 110 in order to mitigate stress generation within the glass core 110 that is induced by the ground plane 109.

The inclusion of such buffer layers 103 is not without issue. Particularly, the addition of a buffer layer increases the cost of manufacturing the package substrate 100. Further, the manufacturing complexity is increased since additional layers are needed. The addition of buffer layers 103 also increases the thickness of the package substrate 100, which may not be desirable in some product segments.

Accordingly, embodiments disclosed herein include electrically conductive features that have a lower volume percentage of metallic material. For example, electrically conductive features may be fabricated with a meshed pattern, which may sometimes also be referred to as a weave pattern. More generally, the electrically conductive features may have a plurality of holes formed through a thickness of the electrically conductive feature. Reducing the volume percentage of the metallic material results in a lower amount of stress being induced into a given area of the underlying glass core. Stated differently, the total stress induced into the glass core by the expansion of the metallic material may be distributed over a larger area so that the stress at any given point on the surface of the glass core is reduced compared to a traditional trace. The stress reduction allows for a more robust glass core that is less prone to cracking and/or other damage.

Since electrically conductive features can be provided directly on the surface of the glass core, the manufacturing complexity of the package substrate is reduced. This can lead to an overall reduction in the cost of the package substrate. Further, the removal of the buffer layers can provide a decrease in the thickness of the package substrate. Accordingly, embodiments disclosed herein provide a significant benefit compared to existing solutions for forming electrically conductive features proximate to the glass core of the package substrate.

In an embodiment, the meshed electrically conductive features described herein may be leveraged in order to provide many different types of interconnect architectures, ground planes, power planes, and/or other electrical features that have at least one layer that directly contacts a surface of the glass core. For example, co-planar waveguides, pseudo microstrip interconnects, microstrip interconnects, strip line interconnects, or the like may be provided directly on the glass core. In each of the different interconnect architectures any of the signal traces, ground planes, or power planes may be meshed and in direct contact with the surface of the glass core.

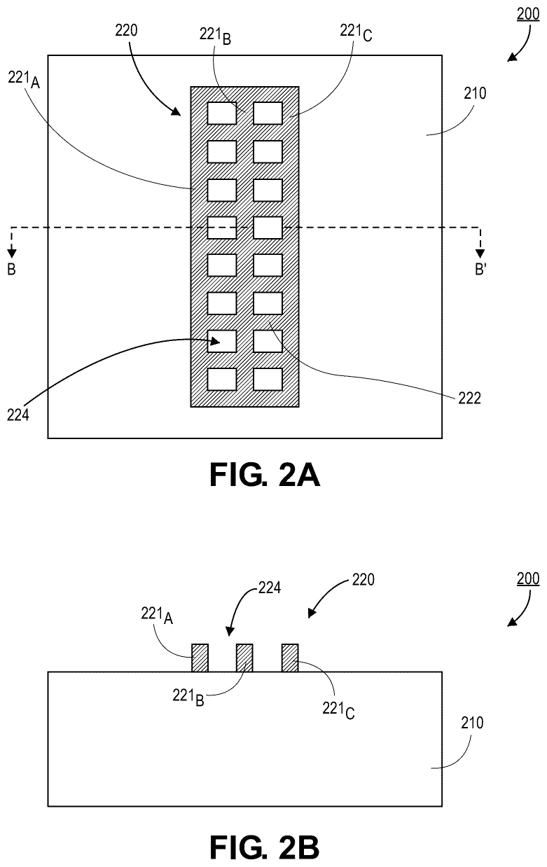

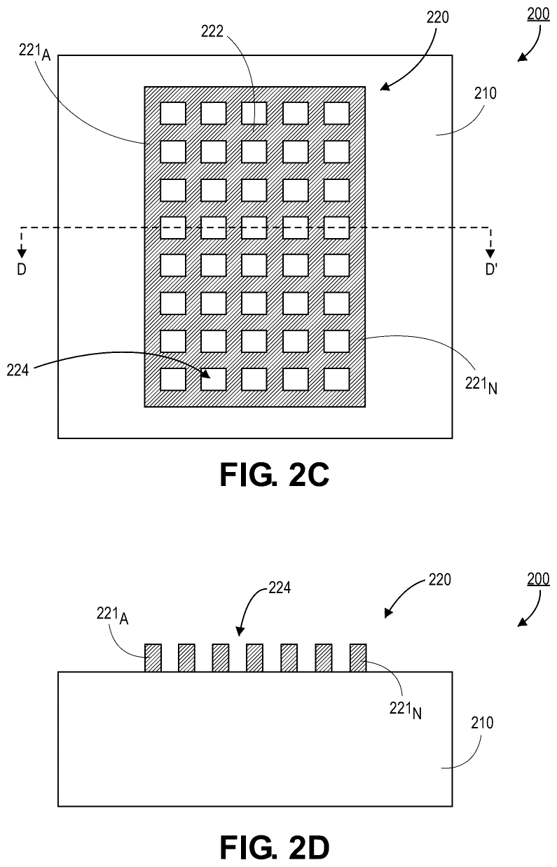

Referring now to FIGS. 2A and 2B, a pair of illustrations depicting a plan view (FIG. 2A) of a portion of a package substrate 200 and a cross-sectional view (FIG. 2B) of the package substrate 200 along line B-B′ is shown, in accordance with an embodiment. In the embodiment shown in FIGS. 2A and 2B, the package substrate 200 comprises a glass core 210. Dielectric buildup layers provided over and/or under the glass core 210 are omitted for simplicity. As shown, an electrically conductive feature 220 is provided on a surface of the glass core 210. In an embodiment, the electrically conductive feature 220 is in direct contact with the surface of the glass core 210. That is, a metallic material (e.g., comprising copper, aluminum, gold, silver, or the like) or a seed layer material used to plate up the electrically conductive feature 220 (e.g., titanium copper (TiCu), ruthenium (Ru), silicon nitride (Si₃N₄), aluminum oxide (Al₂O₃), etc.) makes direct contact with a glass material of the glass core 210.

In an embodiment, the glass core 210 may be substantially all glass. The glass core 210 may be a solid mass comprising a glass material with an amorphous crystal structure where the solid glass core may also include various structures-such as vias, cavities, channels, or other features—that are filled with one or more other materials (e.g., metals, metal alloys, dielectric materials, etc.). As such, glass core 210 may be distinguished from, for example, the “prepreg” or “FR4” core of a Printed Circuit Board (PCB) substrate which typically comprises glass fibers embedded in a resinous organic material, such as an epoxy.

The glass core 210 may have any suitable dimensions. In a particular embodiment, the glass core 210 may have a thickness that is approximately 50 μm or greater. For example, the thickness of the glass core 210 may be between approximately 50 μm and approximately 1.4 mm. Though, smaller or larger thicknesses may also be used. The glass core 210 may have edge dimensions (e.g., length, width, etc.) that are approximately 5 mm or greater. For example, edge dimensions may be between approximately 5 mm to approximately 250 mm. Though, larger or smaller edge dimensions may also be used. More generally, the area dimensions of the glass core 210 (from an overhead plan view) may be between approximately 10 mm×10 mm and approximately 250 mm×250 mm. In an embodiment, the glass core 210 may have a first side that is perpendicular or orthogonal to a second side. In a more general embodiment, the glass core 210 may comprise a rectangular prism volume with sections (e.g., vias) removed and filled with other materials (e.g., metal, etc.).

The glass core 210 may comprise a single monolithic layer of glass. In other embodiments, the glass core 210 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the glass core 210 may each have a thickness less than approximately 50 μm. For example, discrete layers of glass in the glass core 210 may have thicknesses between approximately 25 μm and approximately 50 μm. Though, discrete layers of glass may have larger or smaller thicknesses in some embodiments. As used herein, “approximately” may refer to a range of values within ten percent of the stated value. For example approximately 50 μm may refer to a range between 45 μm and 55 μm.

The glass core 210 may be any suitable glass formulation that has the necessary mechanical robustness and compatibility with semiconductor packaging manufacturing and assembly processes. For example, the glass core 210 may comprise aluminosilicate glass, borosilicate glass, alumino-borosilicate glass, silica, fused silica, or the like. In some embodiments, the glass core 210 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the glass core 210 may comprise silicon and oxygen, as well as any one or more of aluminum, boron, magnesium, calcium, barium, tin, sodium, potassium, strontium, phosphorus, zirconium, lithium, titanium, or zinc. In an embodiment, the glass core 210 may comprise at least 23 percent silicon (by weight) and at least 26 percent oxygen (by weight). In some embodiments, the glass core 210 may further comprise at least 5 percent aluminum (by weight).

In an embodiment, the electrically conductive feature 220 comprises a meshed structure. That is, the electrically conductive feature 220 may comprise a plurality of traces that intersect each other. For example, first traces 221_{A}, 221_{B}, and 221_{C} may be substantially parallel to each other along at least some portions of their length and spaced apart from each other, and cross-member traces 222 may electrically couple two or more of the first traces 221_{A}-221_{C} together. Though, in other embodiments, two or more of the first traces 221_{A}-221_{C} may be non-parallel with each other. In an embodiment, the spacing between adjacent first traces 221_{A}-221_{C} may be substantially uniform. Though, in other embodiments, the spacings may be non-uniform. Similarly, spacings between adjacent cross-member traces 222 may be substantially uniform or non-uniform. In the illustrated embodiment, the cross-member traces 222 are substantially orthogonal to the first traces 221_{A}-221_{C}. Though, the cross-member traces 222 may have any suitable orientation with respect to any of the first traces 221_{A}-221_{C}.

In an embodiment, the meshed pattern of the electrically conductive feature 220 may be considered as being a monolithic structure with a plurality of holes 224 formed through a thickness of the electrically conductive feature 220. In the illustrated embodiment, the holes 224 are substantially uniform in dimension and have a rectangular shape. Though, holes 224 may also have non-uniform dimensions, and/or the holes may have any shape (e.g., with rounded surfaces, circular shapes, triangular shapes, polygonal shapes, and/or the like). Additionally, while the holes 224 are shown as being arranged in a grid-like pattern, the holes 224 may have any suitable arrangement.

In an embodiment, the first traces 221 and the cross-member traces 222 may have any suitable dimension. For example, the widths of first traces 221 and/or cross-member traces 222 may be between approximately 0.5 μm and approximately 20 μm. Though, larger widths may also be used in some embodiments. The first traces 221 and the cross-member traces 222 may have substantially the same width as each other, or the widths may be different. In an embodiment, the spacing between neighboring first traces 221 and/or between neighboring cross-member traces 222 may be between approximately 0.5 μm and approximately 20 μm. Though, larger spacings between neighboring traces may also be used in some embodiments. The thickness of the first traces 221 and the cross-member traces 222 may be between approximately 0.5 μm and approximately 10 μm. Though, any suitable thickness may be used for the traces in other embodiments. The specific trace widths and/or spacings may be chosen in order to minimize the CTE mismatch between the electrically conductive feature 220 and the glass core 210.

In an embodiment, a total area of all of the holes 224 within the electrically conductive feature 220 may account for at least 10 percent of a total area of the electrically conductive feature 220 (as defined as the area enclosed by the outer edges of the electrically conductive feature 220). In other embodiments, the total area of all of the holes 224 may account for at least 20 percent of the total area of the electrically conductive feature 220, at least 50 percent of the total area of the electrically conductive feature 220, or at least 75 percent of the total area of the electrically conductive feature 220.

Increasing the area of the holes 224 reduces the amount of stress that is induced into the underlying glass core 210. However, as the area of the holes 224 increases, the electrical performance may degrade in some instances due to a higher resistance since the cross-sectional area of copper is reduced. Though, slight increases in the footprint of the electrically conductive feature 220 may be used to improve the series resistance and provide substantially equivalent electrical performance to existing trace and/or plane solutions. Additionally, meshed structures may have better electrical performance in high frequency applications (e.g., in the GHz range) due to eddy current improvements attributable to the meshed pattern.

In the illustrated embodiment, the electrically conductive feature 220 includes a series of three first traces 221 and nine cross-member traces 222. Though, it is to be appreciated that any number of first traces 221 and cross-member traces 222 may be used. For example, the electrically conductive feature 220 in FIGS. 2A and 2B may be a replacement for a trace (e.g., to deliver a signal, power, or the like). Though, electrically conductive features 220 with a meshed structure may also be used to generate planes, pads, or other large area features in direct contact with the surface of the glass core 210.

For example, FIGS. 2C and 2D are a plan view illustration (FIG. 2C) of a package substrate 200 and a cross-sectional illustration (FIG. 2D) of the package substrate 200 along line D-D′ where the package substrate 200 has a large area electrically conductive feature 220, in accordance with an embodiment. In an embodiment, the electrically conductive feature 220 in FIGS. 2C and 2D may be similar to the electrically conductive feature 220 in FIGS. 2A and 2B, with the exception of the total area of the electrically conductive feature 220. For example, instead of three first traces 221, a plurality first traces 221_{A}-221_{N} are provided in order to expand the area of the electrically conductive feature 220. Further, While the electrically conductive feature 220 has a substantially rectangular outer footprint, other embodiments may include an electrically conductive feature 220 with an outer perimeter that has any shape.

In FIGS. 2A-2D, the meshed electrically conductive features 220 have generally arbitrary shapes. Though, reference herein may refer to certain meshed electrically conductive features 220 as “traces”, “planes”, “pads”, or the like. Generally, a trace may refer to an electrically conductive feature that is elongated with a length dimension generally longer than a width dimension (in a plan view), and a trace may be used to electrically couple a first point in a circuit to a second point in a circuit. A plane may be a larger area structure with any arbitrary footprint, holes within the plane (e.g., to allow vias to pass through the plane), or the like. Instead of delivering a signal or power from a first position in the circuit to a second position in a circuit, planes may be used to provide a ground reference or any arbitrary voltage reference to other electrical features within a package substrate.

In the embodiments shown in FIGS. 2A-2D, the electrically conductive features 220 are generic examples of meshed structures that may be provided in direct contact with the underlying glass core 210. However, it is to be appreciated that such electrically conductive features 220 may be integrated into larger systems in order to provide different types of electrical interconnects.

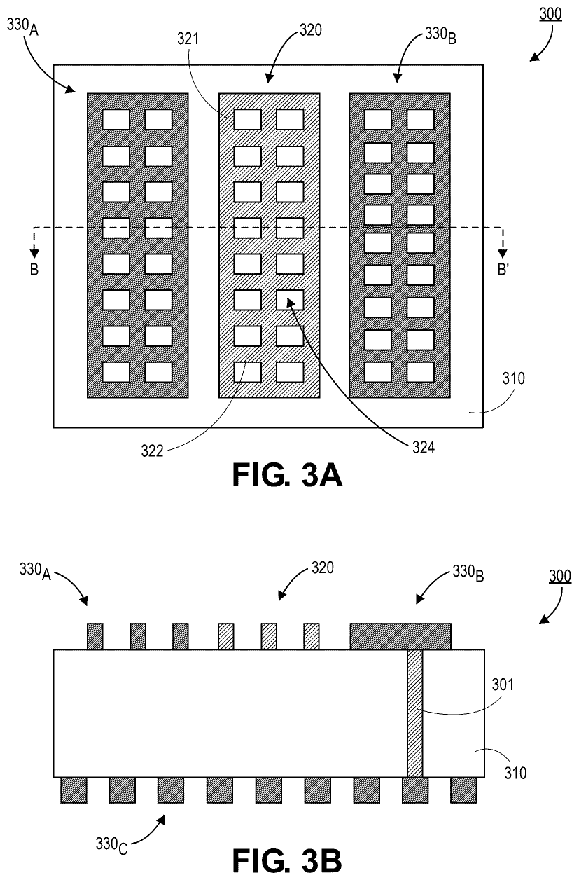

One such interconnect architecture is shown in FIGS. 3A and 3B. FIG. 3A is a plan view illustration of a package substrate 300 that comprises a co-planar waveguide with a meshed structure, and FIG. 3B is a corresponding cross-sectional illustration of the co-planar waveguide along line B-B′ of FIG. 3A. As shown, the co-planar waveguide may comprise a signal trace 320 that is provided between a pair of grounded traces 330_{A} and 330_{B}. The signal trace 320 and the grounded traces 330_{A} and 330_{B} may all have meshed structures that are directly in contact with the underlying glass core 310. For example, the meshed structure may comprise a plurality of first traces 321 with a plurality of cross-member traces 322 that electrically coupled the plurality of first traces 321 together. The meshed structure may result in the formation of holes 324 within the signal trace 320 and the grounded traces 330_{A} and 330_{B}. In an embodiment, the meshed structures of the signal trace 320 and the grounded traces 330_{A} and 330_{B} may be substantially similar to any of the other meshed electrically conductive features described in greater detail herein.

As shown in the cross-sectional illustration of FIG. 3B, a grounded plane 330_{C} may be provided in direct contact with a surface of the glass core 310 opposite from the surface that is in contact with the grounded traces 330_{A} and 330_{B}. In an embodiment, the grounded plane 330_{C} may also have a meshed structure similar to any of the electrically conductive features described in greater detail herein. In some embodiments, a via 301 through the glass core 310 (e.g., a through glass via (TGV)) may electrically couple the grounded trace 330_{B} to the meshed grounded plane 330_{C}.

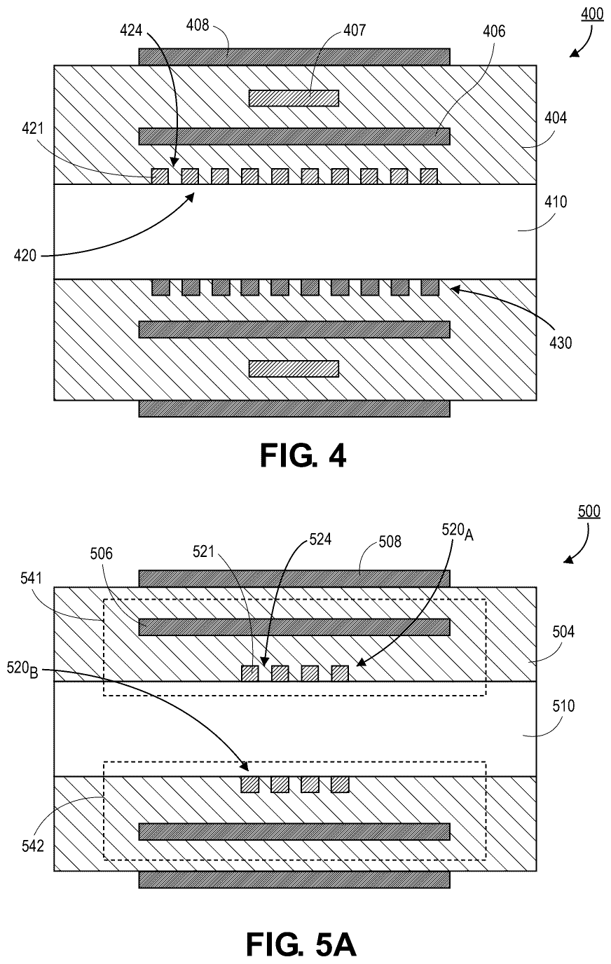

Referring now to FIG. 4, a cross-sectional illustration of a package substrate 400 is shown, in accordance with an additional embodiment. As shown, the package substrate 400 may comprise a glass core 410. The glass core 410 may be similar to any of the glass cores described in greater detail herein. In an embodiment, a meshed interconnect layer 420 may be in direct contact with a surface of the glass core 410, and a meshed ground layer 430 may be in direct contact with an opposing surface of the glass core 410. The meshed structures may include first traces 421 with cross-member traces (not visible in the plane of FIG. 4). For example, the meshed interconnect layer 420 and the meshed ground layer 430 may be similar to any of the meshed electrically conductive features described in greater detail herein.

In an embodiment, dielectric buildup layers 404 may be provided over and under the glass core 410. In an embodiment, the buildup layers 404 may fill the holes 424 formed within the meshed interconnect layer 420 and the meshed ground layer 430. Filling the holes 424 with the buildup layers 404 may improve the adhesion between the buildup layers 404 and the glass core 410 as well. In an embodiment, ground planes 406 and signal traces 407 may be embedded within the buildup layers 404. Since the ground planes 406 and the signal traces 407 are not directly in contact with the glass core 410, the ground planes 406 and the signal traces 407 may be standard monolithic features. Ground planes 408 may also be provided on the surfaces of the buildup layers 404 in some embodiments.

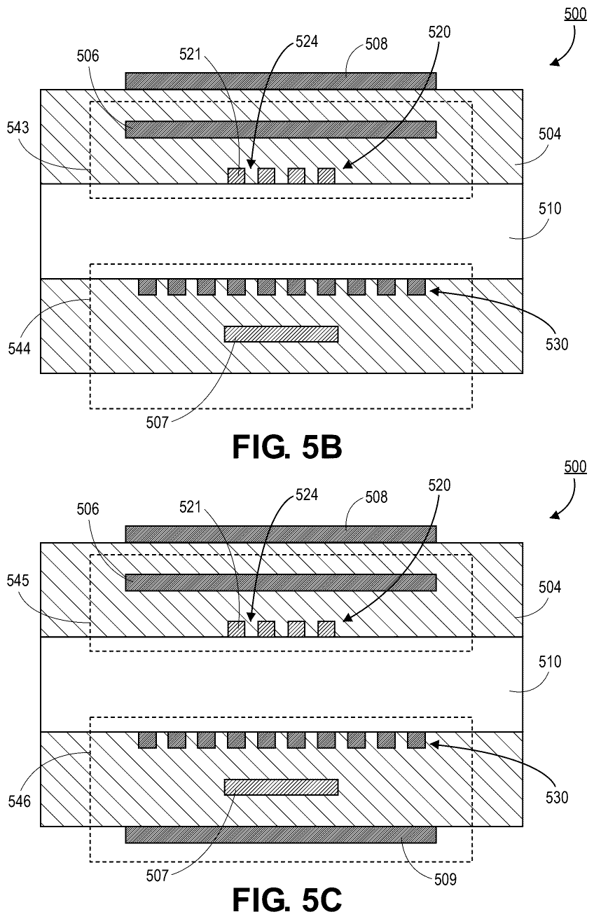

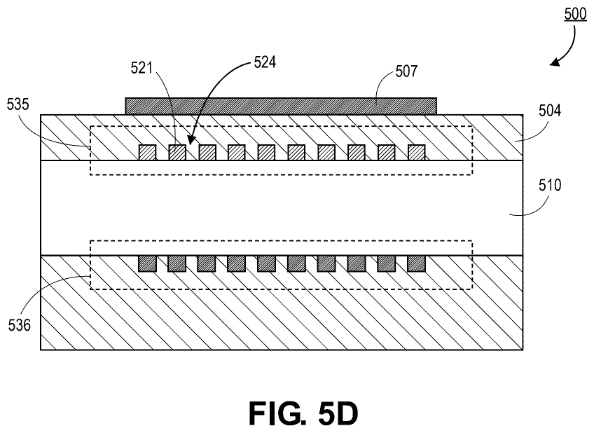

Referring now to FIGS. 5A-5D, a series of package substrates 500 with different interconnect architectures that include meshed electrically conductive features is shown, in accordance with various embodiments. In each of the package substrates 500, dielectric buildup layers 504 are provided over and under the glass core 510.

Referring now to FIG. 5A, the package substrate 500 comprises a first interconnect 541 and a second interconnect 542 that are pseudo microstrips. For example, a meshed signal trace 520_{A} is provided in direct contact with the top surface of the glass core 510 and a meshed signal trace 520_{B} is provided on the bottom surface of the glass core 510. The meshed signal traces 520_{A} and 520_{B} are paired with grounded planes 506 that are embedded within the buildup layers 504. Grounded planes 508 may be provided on the surfaces of the buildup layers 504 in some embodiments as well.

In an embodiment, the meshed signal traces 520_{A} and 520_{B} may be similar to any of the meshed electrically conductive features described in greater detail herein. For example, the meshed signal traces 520_{A} and 520_{B} may include first traces 521 and cross-member traces (not visible in the plane of FIG. 5A). The first traces 521 and the cross-member traces may define a plurality of holes 524 that are filled by portions of the buildup layers 504.

Referring now to FIG. 5B, a cross-sectional illustration of a package substrate 500 is shown, in accordance with an additional embodiment. The package substrate 500 in FIG. 5B is similar to the package substrate 500 in FIG. 5A, with the exception of the bottom interconnect. In an embodiment, the interconnect 543 with meshed trace 520 in FIG. 5B may be similar to the interconnect 541 in FIG. 5A. However, the interconnect 544 in FIG. 5B may be different than the interconnect 542 in FIG. 5A. For example, the interconnect 544 may be an embedded microstrip with a meshed ground plane 530 that is in direct contact with the glass core 510. An embedded trace 507 may be provided in the bottom buildup layer 504 below the meshed ground plane 530. In an embodiment, the meshed ground plane 530 may be similar to any of the meshed electrically conductive features described in greater detail herein.

Referring now to FIG. 5C, a cross-sectional illustration of a package substrate 500 is shown, in accordance with an additional embodiment. In an embodiment, the package substrate 500 in FIG. 5C is similar to the package substrate 500 in FIG. 5B, with the exception of the interconnect type in the bottom buildup layer 504. For example, the interconnect 545 may be similar to the interconnect 543 of FIG. 5B, but the interconnect 546 is a stripline transmission line. For example, a grounded plane 509 may be provided on the surface of the bottom buildup layer 504. As such, the signal trace 507 is between the meshed grounded plane 530 and the monolithic grounded plane 509.

Referring now to FIG. 5D, a cross-sectional illustration of a package substrate 500 is shown, in accordance with an additional embodiment. In an embodiment, the electrically conductive feature 535 may be a meshed power plane, and the electrically conductive feature 536 may be a meshed ground plane. Both electrically conductive features 535 and 536 may comprise traces 521 and cross-member traces (not shown in FIG. 5D) that electrically coupled the traces 521 together. The meshed traces 521 and cross-member traces may define holes 524 that pass through the thicknesses of the electrically conductive features 535 and 536. In an embodiment, the electrically conductive features 535 and 536 may be in direct contact with surfaces of the glass core 510. In an embodiment, the package substrate 500 may also include a plane or trace 507 over the top buildup layer 504.

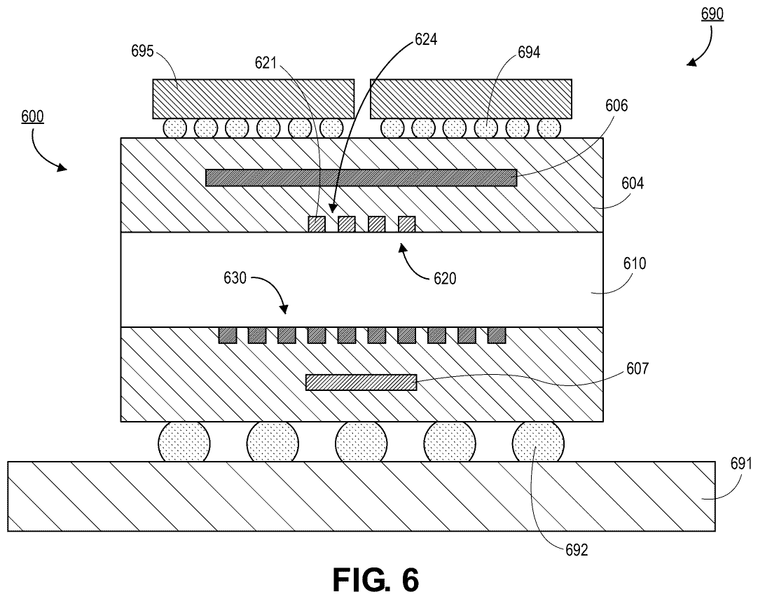

Referring now to FIG. 6, a cross-sectional illustration of an electronic system 690 is shown, in accordance with an embodiment. In an embodiment, the electronic system 690 may comprise a board 691, such as a printed circuit board (PCB), a motherboard, or the like. In an embodiment, the board 691 may be coupled to a package substrate 600 by second level interconnects (SLIs) 692. In an embodiment, the SLIs 692 may comprise solder balls, sockets, or the like.

In an embodiment, the package substrate 600 may be similar to any of the package substrates described in greater detail herein. In an embodiment, the package substrate 600 may comprise a glass core 610 with a meshed signal trace 620 on one surface and a meshed ground plane 630 on the opposite surface. The meshed structures may be similar to any of the meshed electrically conductive features described in greater detail herein. For example, the meshed ground plane 630 and/or the meshed signal trace 620 may have traces 621 that are electrically coupled to each other by cross-member traces (not visible in FIG. 6). The traces 621 and the cross-member traces may define a plurality of holes 624 that pass through the thicknesses of the meshed signal traces 620 or the meshed ground plane 630. Embedded ground planes 606 and/or embedded traces 607 may be provided within the buildup layers 604 of the package substrate 600.

In an embodiment, one or more dies 695 may be coupled to the buildup layer 604 by first level interconnects (FLIs) 694. The FLIs 694 may be any suitable FLI architecture, such as solder balls, copper bumps, hybrid bonding interfaces, or the like. In an embodiment, the one or more dies 695 may be any type of die (e.g., a processor die (e.g., a central processing unit (CPU), a graphics processing unit (GPU), an XPU), a memory die, a communications die, a power management die, and/or the like). In an embodiment, two or more dies 695 may be electrically coupled together by a bridge (not shown) that is embedded in the buildup layer 604 or provided over the buildup layer 604.

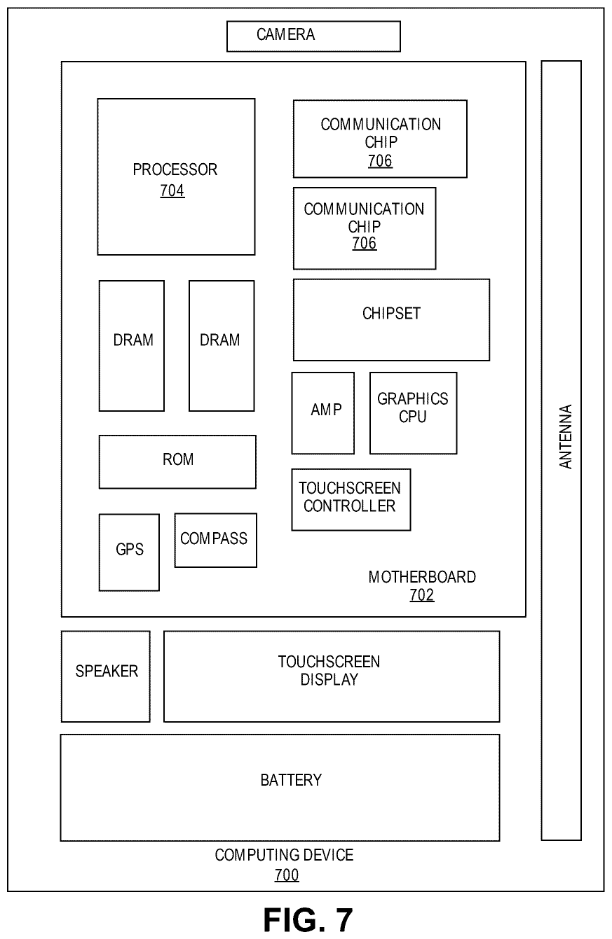

FIG. 7 illustrates a computing device 700 in accordance with one implementation of the disclosure. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704. In an embodiment, a device package is coupled to the board 702. One or both of the processor 704 or the communication chip 706 may be coupled to the board 702 through the device package.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. In some implementations of the disclosure, the integrated circuit die of the processor may be part of a package substrate that comprises a meshed electrically conductive feature in direct contact with a glass core, in accordance with embodiments described herein. The term “processor” may refer to any device or portion of a device that processes electronic data from registers and/or memory to transform that electronic data into other electronic data that may be stored in registers and/or memory.

The communication chip 706 also includes an integrated circuit die packaged within the communication chip 706. In accordance with another implementation of the disclosure, the integrated circuit die of the communication chip may be part of a package substrate that comprises a meshed electrically conductive feature in direct contact with a glass core, in accordance with embodiments described herein.

In an embodiment, the computing device 700 may be part of any apparatus. For example, the computing device may be part of a personal computer, a server, a mobile device, a tablet, an automobile, or the like. That is, the computing device 700 is not limited to being used for any particular type of system, and the computing device 700 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.
Example 1: an apparatus, comprising: a substrate, wherein the substrate comprises a glass layer; and an electrically conductive feature on the substrate, wherein the electrically conductive feature directly contacts the glass layer, and wherein the electrically conductive feature comprises: a layer; and a plurality of holes through the layer, wherein a combined area of the plurality of holes is 20 percent or more of an area defined by an outer perimeter of the layer.
Example 2: the apparatus of Example 1, wherein the plurality of holes are substantially rectangular in shape.
Example 3: the apparatus of Example 1 or Example 2, wherein the plurality of holes are arranged in a grid-like pattern.
Example 4: the apparatus of Examples 1-3, wherein the electrically conductive feature is a trace.
Example 5: the apparatus of Examples 1-4, wherein the electrically conductive feature is a plane.
Example 6: the apparatus of Examples 1-5, wherein the layer comprises copper.
Example 7: the apparatus of Examples 1-6, further comprising: a dielectric layer over the substrate, and wherein the dielectric layer fills the plurality of holes through the layer.
Example 8: an apparatus, comprising: a core, wherein the core comprises a glass layer; a dielectric layer over the core; a first conductive feature embedded within the dielectric layer; and a second conductive feature in direct contact with the glass layer, wherein the second conductive feature comprises a plurality of holes through a thickness of the second conductive feature.
Example 9: the apparatus of Example 8, wherein the first conductive feature comprises a metallic plane.
Example 10: the apparatus of Example 9, wherein the first conductive feature and the second conductive feature are configured to operate as a microstrip interconnect.
Example 11: the apparatus of Example 10, wherein the first conductive feature is configured to be grounded.
Example 12: the apparatus of Example 10, wherein the second conductive feature is configured to be grounded.
Example 13: the apparatus of Example 8, wherein the first conductive feature is a trace, and wherein the first conductive feature is between the second conductive feature and a third conductive feature.
Example 14: the apparatus of Example 13, wherein the first conductive feature, the second conductive feature, and the third conductive feature are configured to operate as a stripline interconnect.
Example 15: the apparatus of Examples 8-14, further comprising: a via through the core, wherein the via is electrically coupled to the second conductive feature.
Example 16: the apparatus of Examples 8-15, wherein the core and the dielectric layer are part of a package substrate.
Example 17: the apparatus of Example 16, further comprising: a die electrically coupled to the package substrate; and a board electrically coupled to the package substrate.
Example 18: an apparatus, comprising: a glass layer; an electrically conductive mesh in direct contact with the glass layer, wherein the electrically conductive mesh comprises: a plurality of first traces, wherein each of the plurality of first traces are substantially parallel to each other; and a plurality of second traces, wherein the plurality of second traces electrically couple the plurality of first traces together.
Example 19: the apparatus of Example 18, wherein at least one of the plurality of second traces is substantially orthogonal to the plurality of first traces.
Example 20: the apparatus of Example 18 or Example 19, wherein spacings between adjacent pairs of the plurality of first traces are substantially equal to each other.

What is claimed is:

1. An apparatus, comprising:
a substrate, wherein the substrate comprises a glass layer; and
an electrically conductive feature on the substrate, wherein the electrically conductive feature directly contacts the glass layer, and wherein the electrically conductive feature comprises:
a layer; and
a plurality of holes through the layer, wherein a combined area of the plurality of holes is 20 percent or more of an area defined by an outer perimeter of the layer.

2. The apparatus of claim 1, wherein the plurality of holes are substantially rectangular in shape.

3. The apparatus of claim 1, wherein the plurality of holes are arranged in a grid-like pattern.

4. The apparatus of claim 1, wherein the electrically conductive feature is a trace.

5. The apparatus of claim 1, wherein the electrically conductive feature is a plane.

6. The apparatus of claim 1, wherein the layer comprises copper.

7. The apparatus of claim 1, further comprising:
a dielectric layer over the substrate, and wherein the dielectric layer fills the plurality of holes through the layer.

8. An apparatus, comprising:
a core, wherein the core comprises a glass layer;
a dielectric layer over the core;
a first conductive feature embedded within the dielectric layer; and
a second conductive feature in direct contact with the glass layer, wherein the second conductive feature comprises a plurality of holes through a thickness of the second conductive feature.

9. The apparatus of claim 8, wherein the first conductive feature comprises a metallic plane.

10. The apparatus of claim 9, wherein the first conductive feature and the second conductive feature are configured to operate as a microstrip interconnect.

11. The apparatus of claim 10, wherein the first conductive feature is configured to be grounded.

12. The apparatus of claim 10, wherein the second conductive feature is configured to be grounded.

13. The apparatus of claim 8, wherein the first conductive feature is a trace, and wherein the first conductive feature is between the second conductive feature and a third conductive feature.

14. The apparatus of claim 13, wherein the first conductive feature, the second conductive feature, and the third conductive feature are configured to operate as a stripline interconnect.

15. The apparatus of claim 8, further comprising:
a via through the core, wherein the via is electrically coupled to the second conductive feature.

16. The apparatus of claim 8, wherein the core and the dielectric layer are part of a package substrate.

17. The apparatus of claim 16, further comprising:
a die electrically coupled to the package substrate; and
a board electrically coupled to the package substrate.

18. An apparatus, comprising:
a glass layer;
an electrically conductive mesh in direct contact with the glass layer, wherein the electrically conductive mesh comprises:
a plurality of first traces, wherein each of the plurality of first traces are substantially parallel to each other; and
a plurality of second traces, wherein the plurality of second traces electrically couple the plurality of first traces together.

19. The apparatus of claim 18, wherein at least one of the plurality of second traces is substantially orthogonal to the plurality of first traces.

20. The apparatus of claim 18, wherein spacings between adjacent pairs of the plurality of first traces are substantially equal to each other.
